(19) United States
(12) Patent Application Publication
(10) Pub. No.: US 2019/0057870 A1
(43) Pub. Date: Feb. 21, 2019

(54) METHOD OF FORMING FINE LINE PATTERNS OF SEMICONDUCTOR DEVICES

(71) Applicant: NANYA TECHNOLOGY CORPORATION, New Taipei City (TW)

(72) Inventors: Shing-Yih SHIH, New Taipei City (TW); Chih-Ching LIN, Taoyuan City (TW); Tzu-Li TSENG, New Taipei City (TW)

(21) Appl. No.: 15/679,176

(22) Filed: Aug. 17, 2017

(51) Int. Cl. H01L 21/033; H01L 21/32; H01L 21/311

(52) U.S. Cl. CPC H01L 21/0337; H01L 21/31144; H01L 21/32

(57) ABSTRACT

A method of forming fine line patterns of semiconductor devices includes: forming a plurality of linear core structures on at least one hard mask layer disposed on a target layer; forming first spacers on sidewalls of the linear core structures; removing the linear core structures; forming second spacers on sidewalls of the first spacers; etching exposed portions of the hard mask layer exposed by the first spacers and the second spacers; and removing the first spacers and the second spacers.

### BACKGROUND

### Technical Field

The present disclosure relates to a method of forming fine line patterns of semiconductor devices.

### Description of Related Art

As the degree of integration of semiconductor devices increases, various double patterning technologies for forming fine line patterns having a pitch or a diameter smaller than the minimum resolution of a photolithography process have been developed.

In general, there are two major double patterning techniques (DPT): Litho-Etch-Litho-Etch (LELE) Double Patterning technique and Self-Aligned Double Patterning (SADP) technique. LELE is much more mature than SADP in terms of process development and design flow implementation, while SADP has stronger scaling potential than LELE due to its smaller design rules on tip-tip and tip-side as well as its intrinsic self-align property.

### SUMMARY

An aspect of the disclosure is to provide a method of forming fine line patterns of semiconductor devices.

According to an embodiment of the disclosure, the method of forming fine line patterns includes: forming a plurality of linear core structures on at least one hard mask layer disposed on a target layer; forming first spacers on sidewalls of the linear core structures; removing the linear core structures; forming second spacers on sidewalls of the first spacers; etching exposed portions of the hard mask layer exposed by the first spacers and the second spacers; and removing the first spacers and the second spacers.

In an embodiment of the disclosure, the forming the linear core structures includes equidistantly forming the linear core structures on the hard mask layer, in which a line width of the linear core structures is substantially equal to a half of a line pitch of the linear core structures.

In an embodiment of the disclosure, the method further includes trimming the linear core structures before the forming the first spacers, in which a line width of the trimmed linear core structures is smaller than a half of the line pitch.

In an embodiment of the disclosure, the line width of the trimmed linear core structures is equal to or greater than a quarter of the line pitch.

In an embodiment of the disclosure, the linear core structures are extended along a first direction and arranged along a second direction.

In an embodiment of the disclosure, the first direction is perpendicular to the second direction.

In an embodiment of the disclosure, the first spacers and the second spacers form a plurality of island structures. Each of the island structures has two line patterns extended along a first direction and arranged along a second direction. A line width of the line patterns is greater than a distance between any adjacent two of the island structures.

In an embodiment of the disclosure, the line width of the line patterns is equal to or greater than a quarter of the line pitch.

In an embodiment of the disclosure, the forming first spacers includes: forming a first spacer layer on a top surface of the hard mask layer, the sidewalls of the linear core structures, and top surfaces of the linear core structures; and removing portions of the first spacer layer on the top surfaces of the hard mask layer and the linear core structures to remain portions of the first spacer layer on the sidewalls of the linear core structures.

In an embodiment of the disclosure, the forming second spacers includes: forming a second spacer layer on a top surface of the hard mask layer, the sidewalls of the first spacers, and top surfaces of the first spacers; and removing portions of the second spacer layer on the top surfaces of the hard mask layer and the first spacers to remain portions of the second spacer layer on the sidewalls of the first spacers.

In an embodiment of the disclosure, a thickness of the first spacers is greater than a thickness of the second spacers.

In an embodiment of the disclosure, the etching includes etching the exposed portions at least until portions of the target layer are exposed by the hard mask layer.

In an embodiment of the disclosure, the removing the linear core structures is performed after the forming the first spacers and before the forming the second spacers.

Accordingly, the method of forming fine line patterns of semiconductor devices of the disclosure can effectively form fine line patterns with narrow space smaller than minimum resolution of a photolithography process.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1A, 2A, 3A, 4A, 5A, 6A, 7A, and 8A are top views illustrating a method of forming fine line patterns of semiconductor devices according to some embodiments of the disclosure; and

FIGS. 1B, 2B, 3B, 4B, 5B, 6B, 7B, and 8B are longitudinal cross-sectional views taken along line A-A′ of FIGS. 1A, 2A, 3A, 4A, 5A, 6A, 7A, and 8A, respectively.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments.

It will be understood that, if an element is referred to as being “connected” or “coupled” to another element, it can be directly connected, or coupled, to the other element or intervening elements may be present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the disclosure provide a method of forming fine line patterns of semiconductor devices.

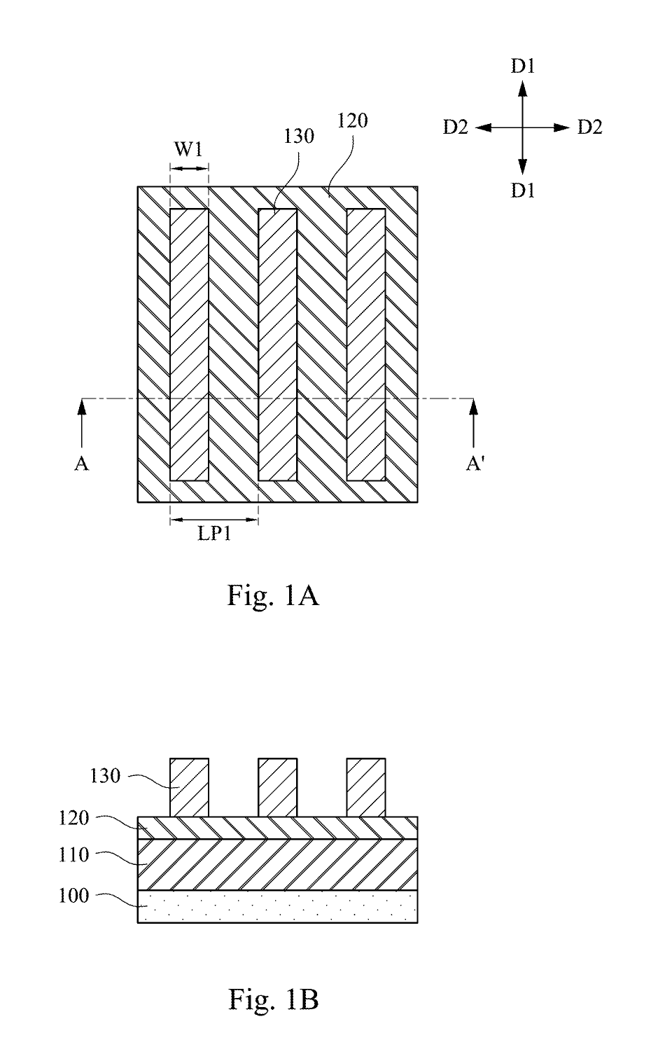

Reference is made to FIGS. 1A and 1B. In some embodiments, the method of forming fine line patterns may include: forming a first hard mask layer 110 on a target layer 100; forming a second hard mask layer 120 on the first hard mask layer 110; and forming a plurality of linear core structures 130 on the second hard mask layer 120.

In some embodiments, the first hard mask layer 110 may include silicon (Si), silicon dioxide (SiO₂), silicon nitride (SiN), silicon oxynitride (SiON), etc. The second hard mask layer 120 may include Si, SiO₂, SiN, SiON, silicon carbide (SiC), etc.

In some embodiments, the forming the linear core structures 130 may include: forming a photoresist layer (not shown) on the second hard mask layer 120; and performing a photolithography process to the photoresist layer to form the linear core structures 130.

In some embodiments, the linear core structures 130 are extended along a first direction D1 and arranged along a second direction D2 (referring to FIG. 1A). In some embodiments, the first direction D1 is perpendicular to the second direction D2, but the disclosure is not limited in this regard.

In some embodiments, the forming the linear core structures 130 includes equidistantly forming the linear core structures 130 on the second hard mask layer 120, in which a line width W1 of the linear core structures 130 is substantially equal to a half of a line pitch LP1 of the linear core structures 130. For example, the line pitch LP1 of the linear core structures 130 may be in a range from 100 nm to 120 nm, and the line width W1 of the linear core structures 130 may be in a range from 50 nm to 60 nm. In some embodiments, the line pitch LP1 of the linear core structures 130 is equal to the minimum line pitch which can be formed by photolithography equipment

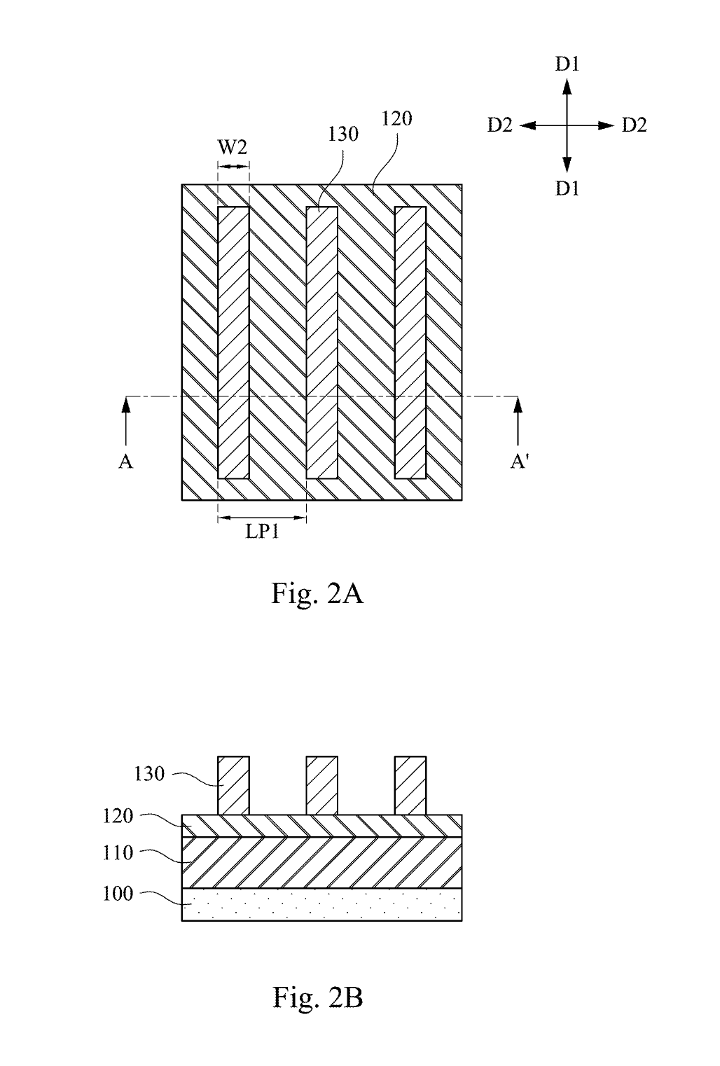

Reference is made to FIGS. 2A and 2B. In some embodiments, the method of forming fine line patterns may further include trimming the linear core structures 130, in which a line width W2 of the trimmed linear core structures 130 is smaller than a half of the line pitch LP1. In some embodiments, the line width W2 of the trimmed linear core structures 130 may be equal to or greater than a quarter of the line pitch LP1. For example, the line pitch LP1 of the linear core structures 130 may be in a range from 100 nm to 120 nm, and the line width W2 of the trimmed linear core structures 130 may be in a range from 40 nm to 50 nm.

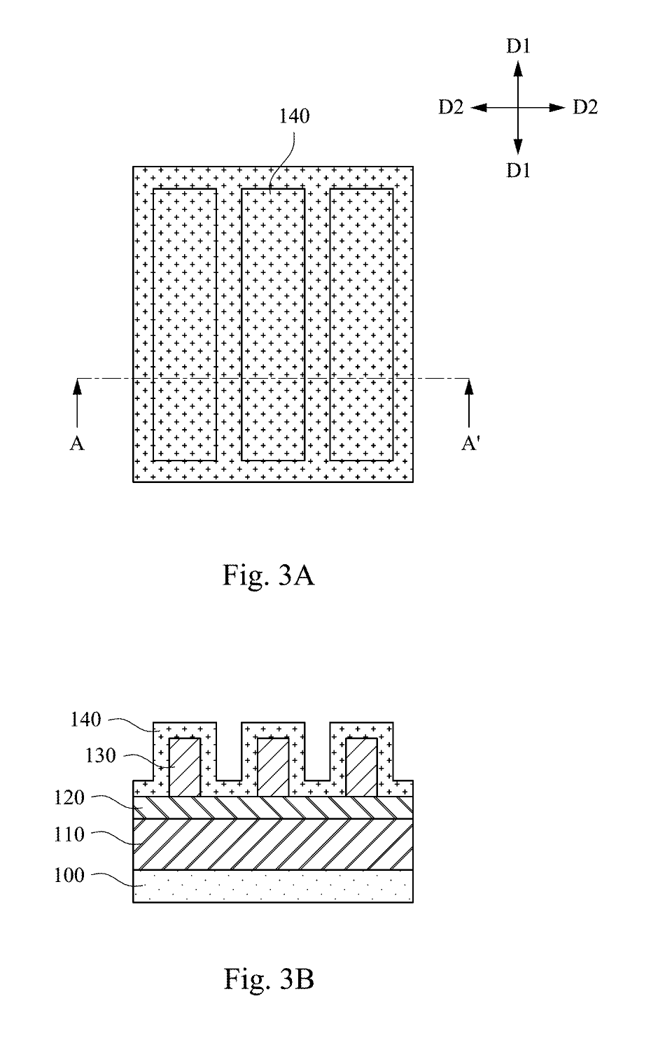

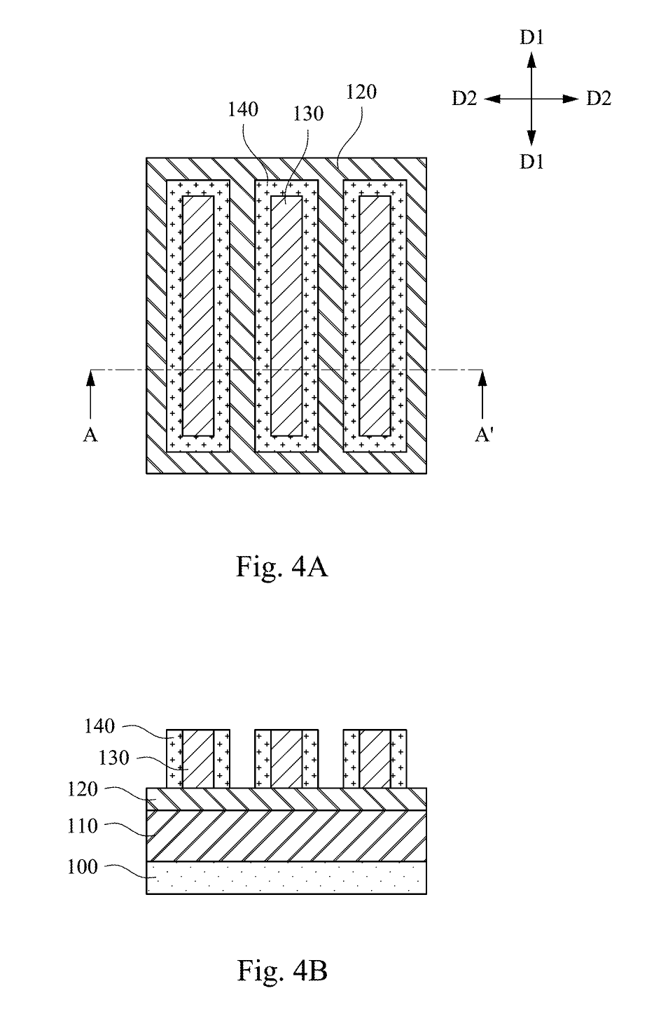

Reference is made to FIG. 3A to FIG. 4B. In some embodiments, the method of forming fine line patterns may further include forming first spacers 140 on sidewalls (i.e., the outer sidewalls) of the linear core structures 130.

In some embodiments, the forming first spacers 140 may include: forming a first spacer layer (not shown) on a top surface of the second hard mask layer 120, the sidewalls of the linear core structures 130, and top surfaces of the linear core structures 130; and removing portions of the first spacer layer on the top surfaces of the second hard mask layer 120 and the linear core structures 130 to remain portions of the first spacer layer on the sidewalls of the linear core structures 130. That is, the remaining portions of the first spacer layer on the outer sidewalls of the linear core structures 130 serve as the first spacers 140.

In some embodiments, the forming the first spacer layer may include blanket forming the first spacer layer by Atomic layer deposition (ALD). In some embodiments, the removing the portions of the first spacer layer on the top surfaces of the second hard mask layer 120 and the linear core structures 130 is performed by etching horizontal portions of the first spacer layer.

In some embodiments, the first spacer layer may include SiN, SiO (silicon monoxide), etc.

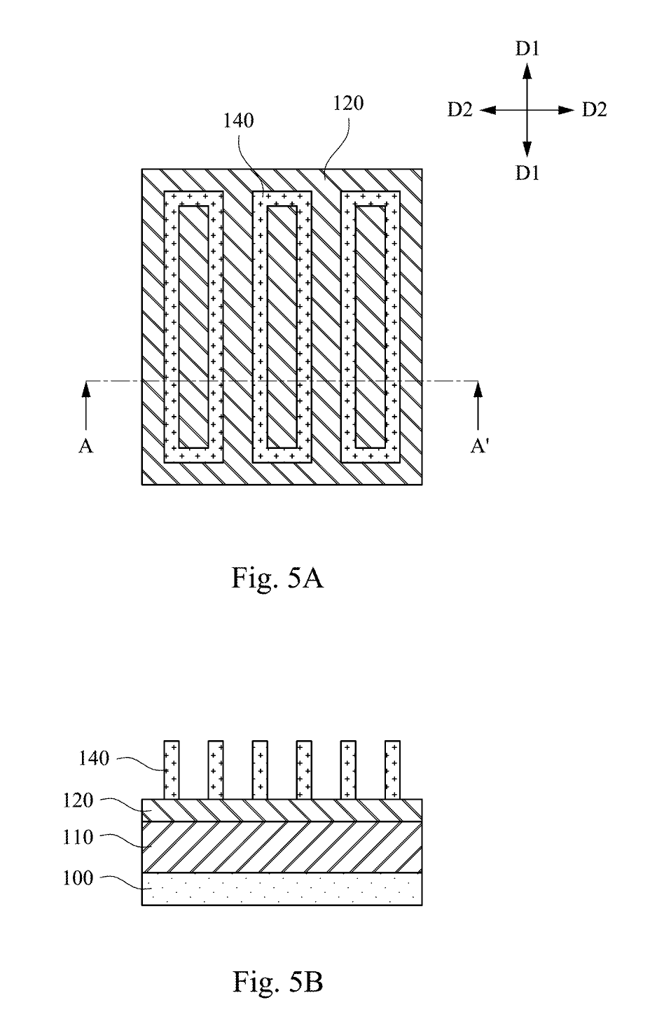

Reference is made to FIGS. 5A and 5B. In some embodiments, the method of forming fine line patterns may further include removing the linear core structures 130. In some embodiments, the linear core structures 130 made of the photoresist layer can be removed by burning off using oxide, but the disclosure is not limited in this regard. After the removal of the linear core structures 130, the first spacers 140 left on the second hard mask layer 120 are ring-shaped.

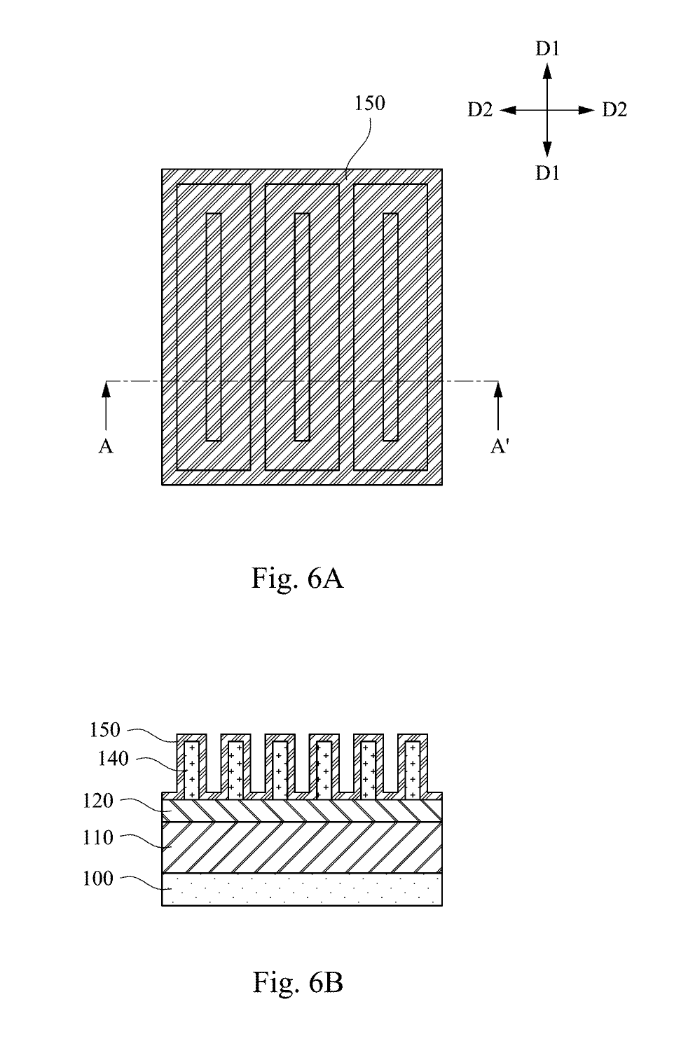

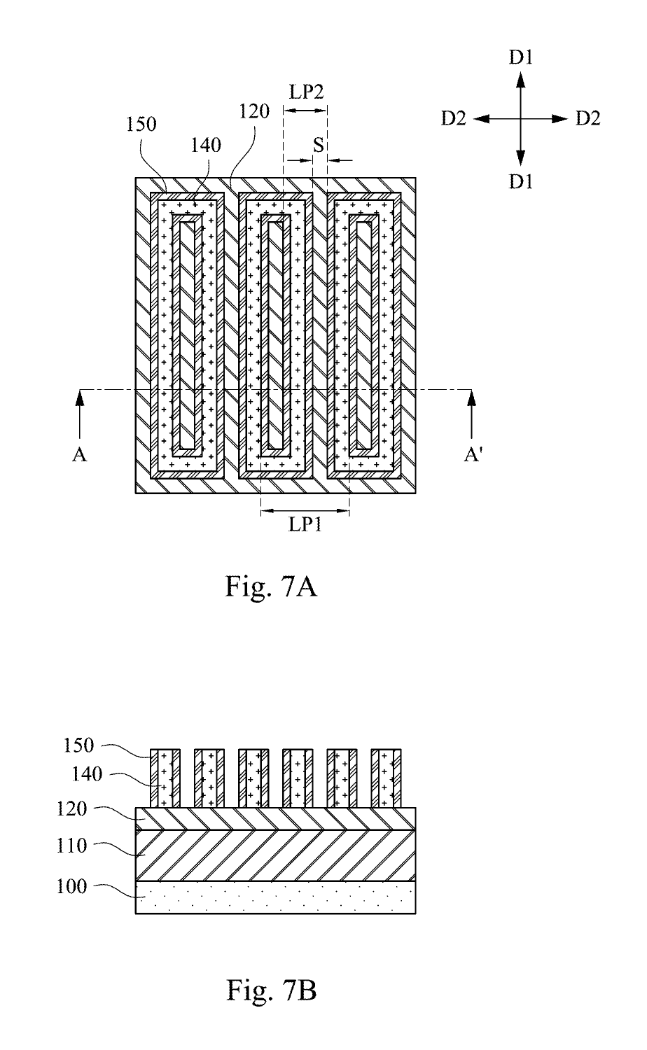

Reference is made to FIG. 6A to FIG. 7B. In some embodiments, the method of forming fine line patterns may further include forming second spacers 150 on sidewalls (including inner and outer sidewalls) of the first spacers 140.

In some embodiments, the forming second spacers 150 may include: forming a second spacer layer (not shown) on a top surface of the second hard mask layer 120, the sidewalls of the first spacers 140, and top surfaces of the first spacers 140; and removing portions of the second spacer layer on the top surfaces of the second hard mask layer 120 and the first spacers 140 to remain portions of the second spacer layer on the sidewalls of the first spacers 140. That is, the remaining portions of the second spacer layer on the inner and outer sidewalls of the first spacers 140 serve as the second spacers 150.

In some embodiments, the forming the second spacer layer may include blanket forming the second spacer layer by ALD. In some embodiments, the removing the portions of the second spacer layer on the top surfaces of the second hard mask layer 120 and the first spacers 140 is performed by etching horizontal portions of the second spacer layer.

In some embodiments, the second spacer layer may include SiN, SiO, etc. In some embodiments, the first spacer layer and the second spacer layer may be formed by the same material(s).

In some embodiments, a thickness of the first spacers 140 is greater than a thickness of the second spacers 150. In some embodiments, the first spacers 140 and the second spacers 150 form a plurality of island structures, in which each of the first spacers 140 is surrounded between corresponding two of the second spacers 150. Each of the island structures has two line patterns extended along the first direction D1 and arranged along the second direction D2 (referring to FIG. 7A). In some embodiments, the line patterns of the island structures may be equidistant in the second direction D2. That is, the line patterns of the island structures may have a constant line pitch LP2 (referring to FIG. 7B).

In some embodiments, a line width W3 of the line patterns (referring to FIG. 7A) is greater than a distance S between any adjacent two of the island structures. In some embodiments, the line width W3 of the line patterns is equal to or greater than a quarter of the line pitch LP1 of the linear core structures 130 (referring to FIG. 7A). For example, the line pitch LP1 of the linear core structures 130 may be in a range from 100 nm to 120 nm, and the line width W3 of the line patterns may be in a range from 40 nm to 50 nm. As a result, the fine line patterns formed by the various embodiments of the disclosure may have narrow space (i.e., the distance S) through multiple deposition/etching processes for linear core structures 130 having a minimum line pitch which can be formed by photolithography equipment.

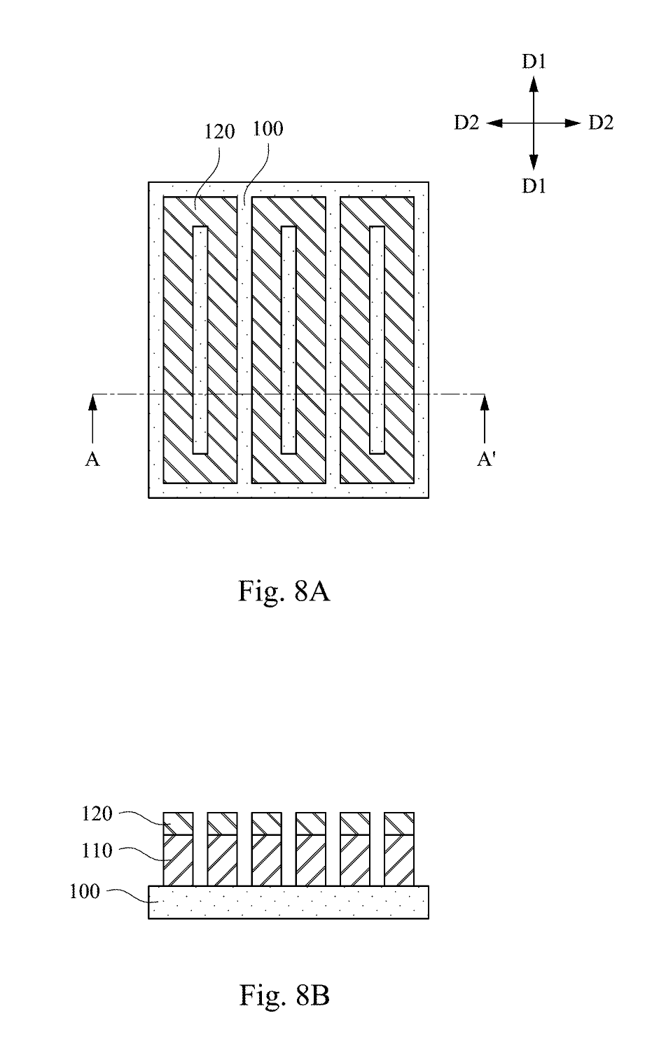

Reference is made to FIGS. 8A and 8B. In some embodiments, the method of forming fine line patterns may further include: etching exposed portions of the second hard mask layer 120 exposed by the first spacers 140 and the second spacers 150; and removing the first spacers 140 and the second spacers 150. In some embodiments, the etching may include etching the exposed portions of the second hard mask layer 120 until portions of the target layer 100 are exposed by the second hard mask layer 120 and the first hard mask layer 110. As a result, the patterns of the line patterns formed by the first spacers 140 and the second spacers 150 can be transferred into the first hard mask layer 110 and the second hard mask layer 120. In some embodiments, the removing the first spacers 140 and the second spacers 150 may be performed by etching.

In some embodiments, the etching may include the etching may include etching the exposed portions of the second hard mask layer 120 until portions of the target layer 100 are etched. As a result, the patterns of the line patterns formed by the first spacers 140 and the second spacers 150 can further be transferred into the target layer 100.

In some embodiments, the target layer 100 is a metal layer formed on a substrate (not shown), but the disclosure is not limited in this regard.

According to the foregoing recitations of the embodiments of the disclosure, it can be seen that the fine line patterns formed by the various embodiments of the disclosure may have narrow space through multiple deposition/etching processes for linear core structures having a minimum line pitch which can be formed by photolithography equipment. Therefore, degree of integration of the semiconductor devices may be improved and the fine line patterns may be stably formed by simple processes since advanced photolithography processes for forming fine line patterns may not be excessively used. In other words, the methods of forming fine line patterns of semiconductor devices according to various embodiments may provide formation of high density line patterns using one photolithography process and deposition and etch back processes of well-known materials without using high-priced semiconductor fabrication equipments, processes, and materials.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A method of forming fine line patterns, the method comprising:
forming a plurality of linear core structures on at least one hard mask layer disposed on a target layer;
forming first spacers on sidewalls of the linear core structures;
removing the linear core structures;
forming second spacers on sidewalls of the first spacers, wherein each of the first spacers is surrounded between corresponding two of the second spacers, and the first spacers and the second spacers are ring-shaped;
etching exposed portions of the hard mask layer exposed by the first spacers and the second spacers; and
removing the first spacers and the second spacers.

2. The method of claim 1, wherein the forming the linear core structures comprising:
equidistantly forming the linear core structures on the hard mask layer, wherein a line width of the linear core structures is substantially equal to a half of a line pitch of the linear core structures.

3. The method of claim 2, further comprising:
trimming the linear core structures before the forming the first spacers, wherein a line width of the trimmed linear core structures is smaller than a half of the line pitch.

4. The method of claim 3, wherein the line width of the trimmed linear core structures is equal to or greater than a quarter of the line pitch.

5. The method of claim 2, wherein the linear core structures are extended along a first direction and arranged along a second direction.

6. The method of claim 5, wherein the first direction is perpendicular to the second direction.

7. The method of claim 2, wherein the first spacers and the second spacers form a plurality of island structures, each of the island structures has two line patterns extended along a first direction and arranged along a second direction, and a line width of the line patterns is greater than a distance between any adjacent two of the island structures.

8. The method of claim 7, wherein the line width of the line patterns is equal to or greater than a quarter of the line pitch.

9. The method of claim 1, wherein the forming the first spacers comprises:
forming a first spacer layer on a top surface of the hard mask layer, the sidewalls of the linear core structures, and top surfaces of the linear core structures; and
removing portions of the first spacer layer on the top surfaces of the hard mask layer and the linear core structures to remain portions of the first spacer layer on the sidewalls of the linear core structures.

10. The method of claim 1, wherein the forming the second spacers comprises:
forming a second spacer layer on a top surface of the hard mask layer, the sidewalls of the first spacers, and top surfaces of the first spacers; and
removing portions of the second spacer layer on the top surfaces of the hard mask layer and the first spacers to remain portions of the second spacer layer on the sidewalls of the first spacers.

11. The method of claim 1, wherein a thickness of the first spacers is greater than a thickness of the second spacers.

12. The method of claim 1, wherein the etching comprises etching the exposed portions at least until portions of the target layer are exposed by the hard mask layer.

13. The method of claim 1, wherein the removing the linear core structures is performed after the forming the first spacers and before the forming the second spacers.
